(19) United States
(12) Patent Application Publication
(10) Pub. No.: US 2025/0293132 A1
(43) Pub. Date: Sep. 18, 2025

(54) CHIP PACKAGING METHOD AND CHIP PACKAGING STRUCTURE

(71) Applicant: TONGFU MICROELECTRONICS CO., LTD., Nantong (CN)

(72) Inventors: Lei SHI, Nantong (CN); Xin XIA, Nantong (CN); Yujuan TAO, Nantong (CN)

(21) Appl. No.: 19/223,671

(22) Filed: May 30, 2025

Related U.S. Application Data
(63) Continuation of application No. PCT/CN2023/136619, filed on Dec. 6, 2023.

(30) Foreign Application Priority Data
Dec. 6, 2022 (CN) 202211553696.1
Dec. 6, 2022 (CN) 202211553758.9
Dec. 6, 2022 (CN) 202211554549.6
Dec. 6, 2022 (CN) 202211555058.3
Dec. 6, 2022 (CN) 202211555419.4
Dec. 6, 2022 (CN) 202211555903.7
Dec. 6, 2022 (CN) 202211556459.0
Dec. 6, 2022 (CN) 202211556609.8
Dec. 6, 2022 (CN) 202211557780.0
Dec. 6, 2022 (CN) 202211557781.5
Dec. 6, 2022 (CN) 202211557789.1
Dec. 6, 2022 (CN) 202211557809.5
Dec. 6, 2022 (CN) 202211558289.X
Dec. 6, 2022 (CN) 202211558474.9
Dec. 6, 2022 (CN) 202211558476.8
Dec. 6, 2022 (CN) 202211578865.7

(51) Int. Cl. H01L 23/498; H01L 21/48; H01L 25/00

(52) U.S. Cl. CPC H01L 23/49827; H01L 21/486; H01L 23/49838; H01L 25/00

(57) ABSTRACT

A chip packaging method and chip packaging structure are provided. The method includes: providing a substrate, a plurality of silicon wafers, and a plurality of chips; forming a plurality of sets of conductive connection structures on the plurality of silicon wafers respectively to form a plurality of silicon interposer plates; where at least one of the plurality of silicon interposer plates is different from other silicon interposer plates of the plurality of silicon interposer plates; cutting the plurality of silicon interposer plates respectively to obtain a plurality of silicon interposer blocks; selecting a plurality of target silicon interposer blocks from the plurality of silicon interposer blocks, and fixing the plurality of target silicon interposer blocks on the substrate; and interconnecting and arranging the plurality of chips on corresponding target silicon interposer blocks of the plurality of target silicon interposer blocks respectively.

### CROSS-REFERENCE TO RELATED APPLICATION

This application is a continuation application of PCT Patent Application No. PCT/CN2023/136619, filed on Dec. 6, 2023, which claims the priority of Chinese Patent Application Nos.: CN202211555058.3, CN202211555419.4, CN202211553696.1, CN202211558289.X, CN202211557781.5, CN202211556609.8, CN202211557809.5, CN202211558476.8, CN202211578865.7, CN202211555903.7, CN202211556459.0, CN202211557789.1, CN202211557780.0, CN202211558474.9, CN202211553758.9, and CN202211554549.6, all filed on Dec. 6, 2022, the contents of all of which are incorporated herein by reference in their entirety.

### TECHNICAL FIELD

The present disclosure generally relates to the field of semiconductor packaging technology and, more particularly, relates to a chip packaging method and a chip packaging structure.

### BACKGROUND

In 2.5D packaging technology, a silicon interposer is mainly an intermediate structure connected between a chip and a substrate to amplify and transmit signals from the chip to the substrate. The chip package becomes thinner and thinner, and a plurality of chips may be connected to the silicon interposer. Therefore, when chips are installed on a silicon interposer and the silicon interposer is thinned, the silicon interposer is prone to warp or even rupture. Also, the integration level of the existing silicon interposer and the chips still needs to be further improved.

### SUMMARY

One aspect of the present disclosure provides a chip packaging method. The method includes: providing a substrate, a plurality of silicon wafers, and a plurality of chips; forming a plurality of sets of conductive connection structures on the plurality of silicon wafers respectively to form a plurality of silicon interposer plates; where at least one of the plurality of silicon interposer plates is different from other silicon interposer plates of the plurality of silicon interposer plates; cutting the plurality of silicon interposer plates respectively to obtain a plurality of silicon interposer blocks; selecting a plurality of target silicon interposer blocks from the plurality of silicon interposer blocks, and fixing the plurality of target silicon interposer blocks on the substrate; and interconnecting and arranging the plurality of chips on corresponding target silicon interposer blocks of the plurality of target silicon interposer blocks respectively.

Another aspect of the present disclosure provides a chip packaging structure. The structure includes: a plurality of silicon interposers; a first plastic encapsulation layer wrapping the plurality of silicon interposers; and a plurality of chips. Each of the plurality of silicon interposers is provided with conductive connection structures and conductive connection structures of at least one of the plurality of silicon interposers are different from conductive connection structures of others of the plurality of silicon interposers. The plurality of chips is interconnected to the plurality of silicon interposers through a bonding structure.

### BRIEF DESCRIPTION OF THE DRAWINGS

The following drawings are merely examples for illustrative purposes according to various disclosed embodiments and are not intended to limit the scope of the present disclosure.

FIG. 1 illustrates an exemplary chip packaging method according to various disclosed embodiments of the present disclosure.

FIG. 2 illustrates an exemplary method for forming a silicon interposer plate according to various disclosed embodiments of the present disclosure.

FIG. 3 illustrates another exemplary method for forming a silicon interposer plate according to various disclosed embodiments of the present disclosure.

FIG. 4 illustrates another exemplary method for forming a silicon interposer plate according to various disclosed embodiments of the present disclosure.

FIG. 5 illustrates an exemplary chip interconnection and arrangement method according to various disclosed embodiments of the present disclosure.

FIG. 6 illustrates another exemplary chip interconnection and arrangement method according to various disclosed embodiments of the present disclosure.

FIG. 7 illustrates another exemplary chip interconnection and arrangement method according to various disclosed embodiments of the present disclosure.

FIG. 8 illustrates another exemplary chip interconnection and arrangement method according to various disclosed embodiments of the present disclosure.

FIG. 9 illustrates another exemplary chip interconnection and arrangement method according to various disclosed embodiments of the present disclosure.

FIG. 10 illustrates another exemplary chip interconnection and arrangement method according to various disclosed embodiments of the present disclosure.

FIG. 11 illustrates another exemplary chip interconnection and arrangement method according to various disclosed embodiments of the present disclosure.

FIG. 12 illustrates another exemplary chip interconnection and arrangement method according to various disclosed embodiments of the present disclosure.

FIG. 13 illustrates another exemplary chip interconnection and arrangement method according to various disclosed embodiments of the present disclosure.

FIG. 14 illustrates another exemplary chip interconnection and arrangement method according to various disclosed embodiments of the present disclosure.

### DETAILED DESCRIPTION

Reference will now be made in detail to exemplary embodiments of the disclosure, which are illustrated in the accompanying drawings. Wherever possible, the same reference numbers will be used throughout the drawings to refer to the same or like parts.

It should be noted that “surface” or “upper” in this specification are used to describe the relative positional relationship in space, and are not limited to whether the components are in direct contact.

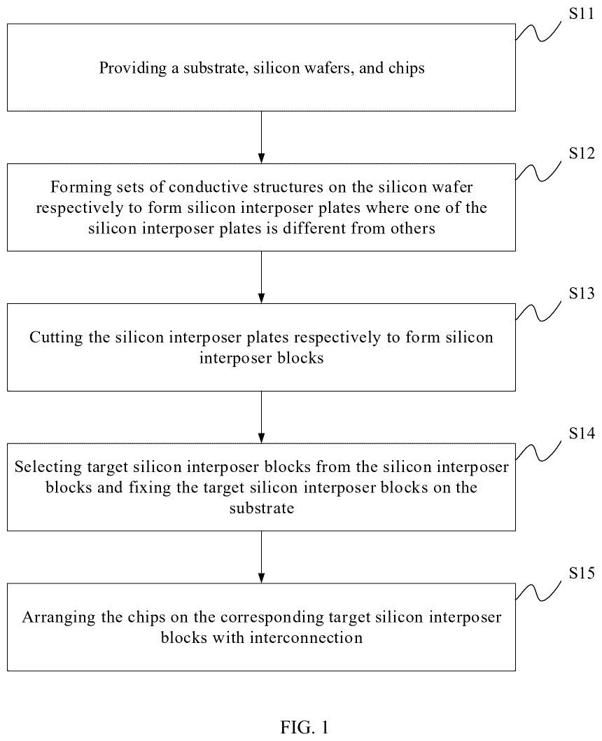

One embodiment of the present disclosure provides a chip packaging method. As shown in FIG. 1, the method may include, for example, S11 to S15.

In S11, a substrate, a plurality of silicon wafers, and a plurality of chips may be provided.

In one embodiment, the plurality of silicon wafers may be used to form a plurality of silicon interposers of different specifications.

Three different types of substrates may be provided. The first type of substrate may be a conventional substrate, which is in the shape of a plate with at least two upper and lower flat surfaces. The second type of substrate may be based on the first type of substrate, and a plurality of grooves may be etched at various predetermined positions on one of the flat surfaces. For the convenience of description, the embodiments where the depths of the plurality of grooves are all equal will be used as examples to illustrate the present disclosure. In the third type of substrate, each predetermined position on one of the flat surfaces may be etched through to form a plurality of through grooves.

In one embodiment, the plurality of chips may be chips to be packaged in the embodiment of the present disclosure.

In one embodiment, the plurality of chips may include a plurality of heterogeneous chips, and “heterogeneous” may mean that the specifications of each single chip of the plurality of chips may be arbitrary.

The chip packaging method provided by the embodiments of the present disclosure may be applied to a variety of different substrates and chips with a variety of different specifications, and may meet various packaging requirements in modern chip packaging technology.

In one embodiment, the plurality of chips may be fixed on a carrier plate and plastic-sealed, and then the carrier plate may be removed to obtain a chip reassembly. Therefore, the plurality of predetermined chips may be packaged into a whole body for subsequent bonding with a silicon interposer and a substrate. The process may be reduced, to facilitate operation and improve the overall integration level.

In S12, a plurality of sets of conductive connection structures may be formed on the plurality of silicon wafers respectively, to form a plurality of silicon interposer plates. At least one of the plurality of silicon interposer plates may be different from others of the plurality of silicon interposer plates.

Various embodiments of the present disclosure may provide six types of silicon interposer plates by using formation processes as distinctions. Each type of silicon interposer plate may further be subdivided into multiple different types according to the different depths, widths, densities, etc. of holes formed. Only one type of silicon interposer plate may be produced from one silicon wafer.

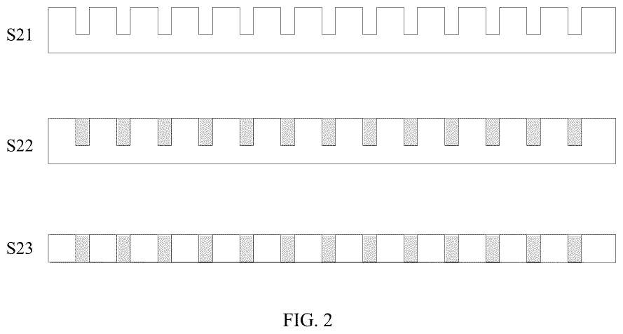

In one embodiment, the first type of silicon interposer plate may be formed, as shown in FIG. 2. Each silicon wafer may include a first surface and a second surface along its thickness direction. Forming the plurality of sets of conductive connection structures on the plurality of silicon wafers to form the plurality of silicon interposer plates may include:

S21: forming a plurality of sets of blind holes on the first surface of at least one silicon wafer; and

S22: filling the plurality of sets of blind holes with conductive materials to form the plurality of sets of conductive connection structures and the plurality of silicon interposer plates.

In one embodiment, the second type of silicon interposer plate may be formed, as shown in FIG. 2. Each silicon wafer may include a first surface and a second surface along its thickness direction. Forming the plurality of sets of conductive connection structures on the plurality of silicon wafers to form the plurality of silicon interposer plates may include:

S21: forming a plurality of sets of blind holes on the first surface of at least one silicon wafer;

S22: filling the plurality of sets of blind holes with conductive materials to form the plurality of sets of conductive connection structures; and

S23: thinning second surfaces of the plurality of silicon wafers, to form the plurality of silicon interposer plates.

In one embodiment, the second surfaces of the plurality of silicon wafers may be thinned until exposing the plurality of sets of blind holes, to form through holes and the plurality of silicon interposer plates.

In one embodiment, the second surfaces of the plurality of silicon wafers may be thinned until exposing the plurality of sets of conductive connection structures to form through holes plurality of silicon interposer plates.

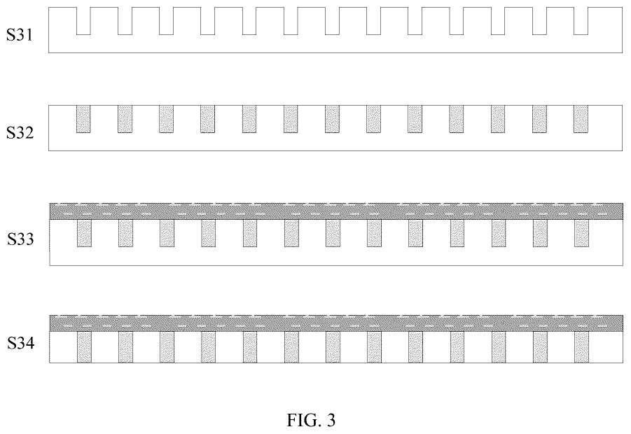

In one embodiment, the third type of silicon interposer plate may be formed, as shown in FIG. 3. Each silicon wafer may include a first surface and a second surface along its thickness direction. Forming the plurality of sets of conductive connection structures on the plurality of silicon wafers respectively to form the plurality of silicon interposer plates may include:

S31: forming a plurality of sets of blind holes on the first surface of at least one silicon wafer;

S32: filling the plurality of sets of blind holes with conductive materials; and

S33: forming a redistribution layer (RDL) on the first surface of the at least one silicon wafer, to form a plurality of sets of conductive connection structures and the plurality of silicon interposer plates.

In one embodiment, the fourth type of silicon interposer plate may be formed, as shown in FIG. 3. Each silicon wafer may include a first surface and a second surface along its thickness direction. Forming the plurality of sets of conductive connection structures on the plurality of silicon wafers respectively to form the plurality of silicon interposer plates may include:

S31: forming a plurality of sets of blind holes on the first surface of at least one silicon wafer;

S32: filling the plurality of sets of blind holes with conductive materials; and

S33: forming a redistribution layer (RDL) on the first surface of the at least one silicon wafer to form a plurality of sets of conductive connection structures; and

S34: thinning the second surface of the at least one silicon wafer to form the plurality of silicon interposer plates.

In one embodiment, the second surfaces of the plurality of silicon wafers may be thinned until exposing the plurality of sets of blind holes, to form through holes and the plurality of silicon interposer plates.

In one embodiment, the second surfaces of the plurality of silicon wafers may be thinned until exposing the plurality of sets of conductive connection structures to form through holes plurality of silicon interposer plates.

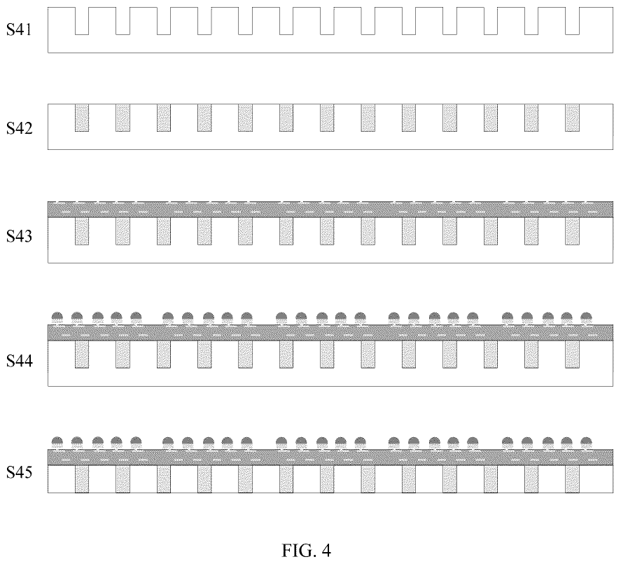

In one embodiment, the fourth type of silicon interposer plate may be formed, as shown in FIG. 4. Each silicon wafer may include a first surface and a second surface along its thickness direction. Forming the plurality of sets of conductive connection structures on the plurality of silicon wafers respectively to form the plurality of silicon interposer plates may include:

S41: forming a plurality of sets of blind holes on the first surface of at least one silicon wafer;

S42: filling the plurality of sets of blind holes with conductive materials; and S43: forming a redistribution layer (RDL) on the first surface of the at least one silicon wafer;

S44: forming bumps on the redistribution layer to form the plurality of sets of conductive connection structures and the plurality of silicon interposer plates.

In one embodiment, the fourth type of silicon interposer plate may be formed, as shown in FIG. 4. Each silicon wafer may include a first surface and a second surface along its thickness direction. Forming the plurality of sets of conductive connection structures on the plurality of silicon wafers respectively to form the plurality of silicon interposer plates may include:

S41: forming a plurality of sets of blind holes on the first surface of at least one silicon wafer;

S42: filling the plurality of sets of blind holes with conductive materials; and S43: forming a redistribution layer (RDL) on the first surface of the at least one silicon wafer;

S44: forming soldering bumps on the redistribution layer to form the plurality of sets of conductive connection structures; and

S45: thinning the second surface of the at least one silicon wafer to form the plurality of silicon interposer plates.

In one embodiment, the second surfaces of the plurality of silicon wafers may be thinned until exposing the plurality of sets of blind holes, to form through holes and the plurality of silicon interposer plates.

In one embodiment, the second surfaces of the plurality of silicon wafers may be thinned until exposing the plurality of sets of conductive connection structures to form through holes plurality of silicon interposer plates.

The present disclosure provides multiple types of silicon interposer plates with different conductive connection structures, to meet different packaging requirements in conjunction with the multiple types of substrates and the plurality of chips.

In S13, the plurality of silicon interposer plates may be cut respectively to obtain a plurality of silicon interposer blocks.

In one embodiment, by cutting different silicon interposer plates obtained in the above steps, the plurality of silicon interposer blocks of various specifications may be obtained. The conductive connection structures, depth, width, or density of holes in each type of silicon interposer block may be different.

In the present disclosure, a large silicon interposer plate may be cut into small silicon interposer blocks, thereby avoiding the warping and cracking of the silicon interposer during the thinning process. Different types of silicon interposer blocks may be arbitrarily combined according to packaging requirements to improve integration.

In one embodiment, the height of all of the plurality of silicon interposer blocks may be the same.

In S14, a plurality of target silicon interposer blocks may be selected from the plurality of silicon interposer blocks, and the plurality of target silicon interposer blocks may be fixed on the substrate.

In one embodiment, according to the pin arrangement of the chips to be packaged, and if the substrate is provided with grooves or through grooves, according to the positions of the grooves or through grooves, the silicon interposer blocks to be used in the packaging process may be determined, such the conductive connection structures on the silicon interposer blocks are able to be connected correspondingly to the pins of the chips to facilitate conduction. The silicon interposer blocks selected may be the target silicon interposer blocks. The target silicon interposer blocks may be fixed to corresponding positions or in corresponding grooves on the substrate.

In the present disclosure, the silicon interposer blocks of different specifications may be mounted on the substrate in any combination, such that the plurality of chips of different specifications may be installed on corresponding silicon interposer blocks as needed, thereby improving the overall integration level.

In one embodiment, when the plurality of target silicon interposer blocks is fixed on the substrate, first surfaces of at least one of the plurality of target silicon interposer blocks may be fixed in the corresponding grooves, and second surfaces of remaining target silicon interposer blocks of the plurality of target silicon interposer blocks may be fixed in the corresponding grooves.

In one embodiment, the thickness of at least one of the plurality of target silicon interposer blocks may be lower than the height of the corresponding grooves of the substrate.

In one embodiment, the plurality of target silicon interposer blocks may be fixed in the corresponding grooves on the substrate with the first surfaces facing outward.

In one embodiment, the thickness of at least one of the plurality of target silicon interposer blocks may be different from remaining target silicon interposer blocks of the plurality of target silicon interposer blocks. The plurality of target silicon interposer blocks may be fixed in the corresponding grooves on the substrate with the first surfaces (that is, the opening direction of the blind holes) facing outward.

In one embodiment, the thickness of at least one of the plurality of target silicon interposer blocks may be different from remaining target silicon interposer blocks of the plurality of target silicon interposer blocks. When the plurality of target silicon interposer blocks is fixed on the substrate, first surfaces of at least one of the plurality of target silicon interposer blocks may be fixed in the corresponding grooves, and second surfaces of at least one of remaining target silicon interposer blocks of the plurality of target silicon interposer blocks may be fixed in the corresponding grooves.

In S15, the plurality of chips may be respectively disposed on the corresponding plurality of target silicon interposer blocks with interconnection.

In one embodiment, before and after S15, there may be multiple sets of different implementation processes that need to be completed in parallel for different styles of substrates and different types of target silicon interposer blocks and their placement in grooves. To enable those skilled in the art to realize the technical effects of the present disclosure and to make the technical solution of the present disclosure clear and complete, some examples of different implementation processes are illustrated below.

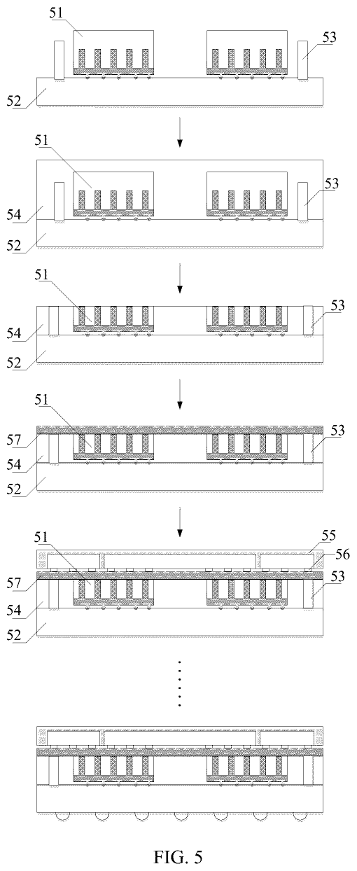

In one embodiment shown in FIG. 5, the plurality of target silicon interposer blocks 51 with blind holes and a planar substrate 52 may be selected. The first surface with opening blind holes of each target silicon interposer block 51 may be fixed at a corresponding position on the surface of the substrate 52.

Subsequently, a plurality of conductive pillars 53 may be prefabricated in an empty space on the substrate 52 where the plurality of target silicon interposer blocks 51 is not fixed. The plurality of conductive pillars 53 may be copper pillars, and the height of the plurality of conductive pillars 53 may be larger than the height of the lowest blind holes. The plastic encapsulation may be performed to the plurality of target silicon interposer blocks 51 and the plurality of conductive pillars 53 on the substrate 52 integrally to form a plastic encapsulation layer 54.

The plastic encapsulation layer 54 may be then polished and thinned until all blind holes are exposed, that is, until all blind holes become through holes. At this time, the plurality of conductive pillars 53 may also be exposed.

A redistribution layer may be formed on the thinned plane, and the chip reassembly 55 mentioned above may be flipped and installed on the redistribution layer 57 through the bumps 56 to complete the interconnection and arrangement of the plurality of chips on the plurality of silicon interposer blocks.

In another embodiment, that “the plurality of conductive pillars 53 may be prefabricated in an empty space on the substrate 52 where the plurality of target silicon interposer blocks 51 is not fixed. The plurality of conductive pillars 53 may be copper pillars, and the height of the plurality of conductive pillars 53 may be larger than the height of the lowest blind holes. Integral plastic encapsulation may be performed on the plurality of target silicon interposer blocks 51 and the plurality of conductive pillars 53 on the substrate 52 to form a plastic encapsulation layer 54” may be replaced by:

“Integral plastic encapsulation may be performed on the plurality of target silicon interposer blocks, to form the plastic encapsulation layer. And then the TMV process may be performed along the thickness direction of the plastic encapsulation layer to form through holes and the through holes may be filled with conductive materials, such as copper, etc., to form the plurality of conductive pillars.” When opening the through holes in the plastic encapsulation layer using the TMV process, attention may be paid to protecting the substrate.

Additionally, bumping may be performed on a side of the substrate 52 away from the plurality of target silicon interposer blocks 51 for more possible operations in the process, such as stacking of chips.

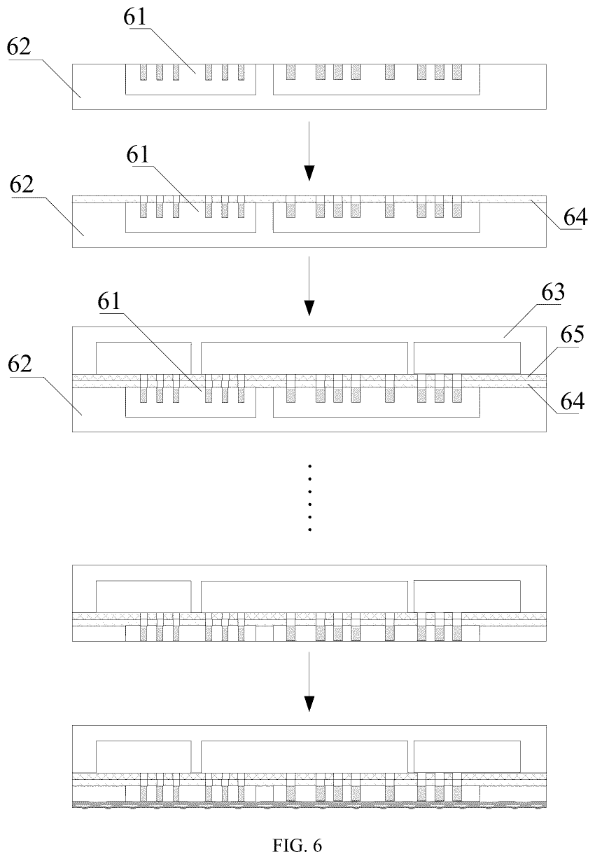

In another embodiment shown in FIG. 6, the plurality of target silicon interposer blocks 61 with blind holes and the same height and a substrate 62 with grooves etched at corresponding positions may be selected. The plurality of target silicon interposer blocks 61 may be fixed in corresponding grooves on the substrate 62 with their blind hole openings facing outward. The height of all of the plurality of target silicon interposer blocks 61 may be exactly equal to the depth of the grooves, that is, the outer surfaces of all of the plurality of target silicon interposer blocks 61 may be flush with the surface of the substrate 62 other than the groove.

A first bonding structure 64 may be formed on the flush surface, and a second bonding structure 65 may be formed on a side of the chip reassembly 63 mentioned above with chips.

The first bonding structure 64 and the second bonding structure 65 may be correspondingly fixed together to complete the interconnection and arrangement of the plurality of chips on the plurality of target silicon interposer blocks.

Further, the side of the substrate away from the grooves may be thinned later until all the blind holes of the plurality of target silicon interposer blocks are exposed, and redistribution (RDL), bumping, etc. may be performed on the thinned surface for more possible operations in the process, such as stacking of chips, etc.

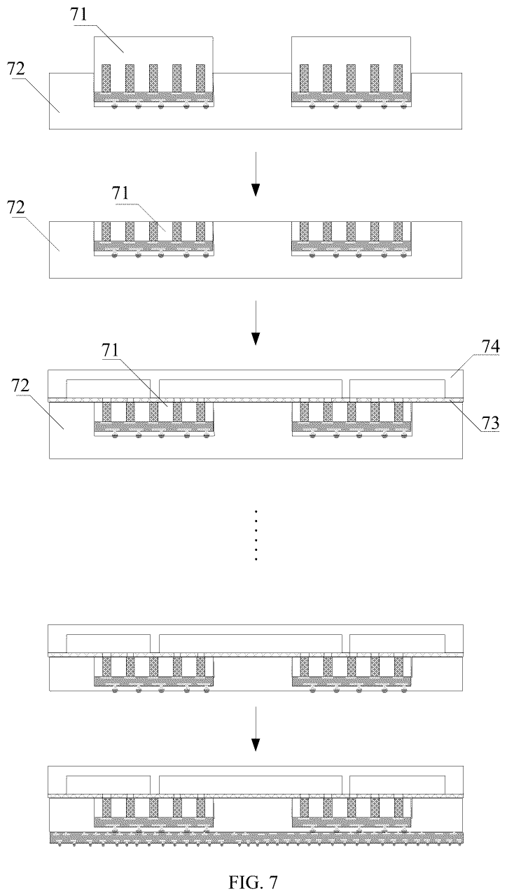

In another embodiment shown in FIG. 7, the plurality of target silicon interposer blocks 71 with blind holes and a substrate 72 with grooves etched at corresponding positions may be selected. The plurality of target silicon interposer blocks 71 may be fixed in corresponding grooves on the substrate 72 with their blind hole openings facing inward. The height of all blind holes of the plurality of target silicon interposer blocks 71 may be higher than or flush with the surface of the substrate 72 other than the groove.

The plurality of target silicon interposer blocks 71 may be polished and thinned to be flush with the surface of the substrate 72 except for the grooves. At this time, all the blind holes of the plurality of target silicon interposer blocks 71 may also be exposed.

A bonding structure 73 may be provided on the thinned flush surface, and the aforementioned chip reassembly 74 may be fixed on the plurality of target silicon interposer blocks 71 through the bonding structure 73 to complete the interconnection and arrangement of the plurality of chips on the plurality of target silicon interposer blocks.

Further, the side of the substrate away from the grooves may be thinned later until the plurality of target silicon interposer blocks is exposed, and redistribution (RDL), bumping, etc. may be performed on the thinned surface for more possible operations in the process, such as stacking of chips, etc.

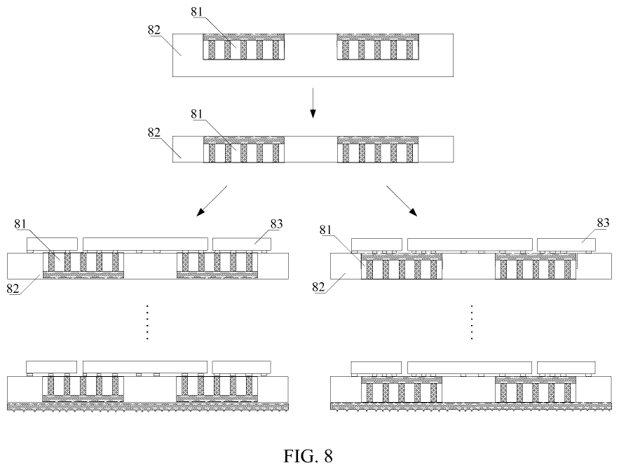

In another embodiment shown in FIG. 8, the plurality of target silicon interposer blocks 81 with through holes and a substrate 82 with etched grooves previously may be selected. The depth of the grooves may be same as the height of the plurality of target silicon interposer blocks 81.

The plurality of target silicon interposer blocks 81 may be fixed in corresponding grooves on the substrate 82, and a side of the substrate 82 away from the grooves may be polished and thinned, until exposing the plurality of target silicon interposer blocks 81.

The plurality of chips 83 with different specifications may be fixed on the corresponding plurality of target silicon interposer blocks 81. The plurality of chips 83 may be fixed on a side of the plurality of target silicon interposer blocks 81 with conductive connection structures or a side of the plurality of target silicon interposer blocks 81 exposed after thinning, to complete the interconnection and arrangement of the plurality of chips on the plurality of target silicon interposer blocks.

Further, redistribution (RDL), bumping, etc. may be performed on a side of the substrate and a side of the plurality of target silicon interposer blocks 81 without bonding with chips, for more possible operations in the process, such as stacking of chips, etc.

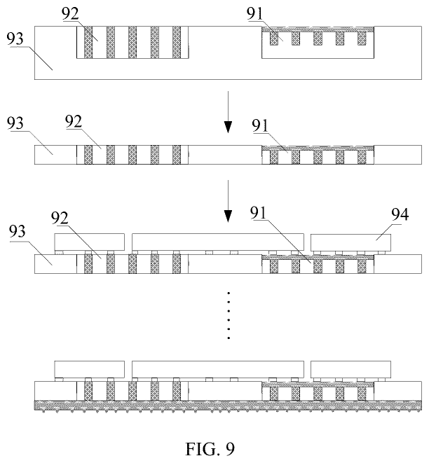

In one embodiment shown in FIG. 9, a plurality of target silicon interposer blocks 91 with blind holes and a plurality of target silicon interposer blocks 92 with through holes, as well as a substrate 93 with grooves etched in advance may be selected. The depth of the grooves may be consistent with the height of all the plurality of target silicon interposer blocks.

The plurality of target silicon interposer blocks 91 with blind holes may be respectively fixed in the corresponding grooves etched in advance on the substrate 93 with the blind hole opening direction facing outward.

The side of the substrate 93 away from the grooves may be polished and thinned until all blind holes are exposed. At this point, all the plurality of target silicon interposer blocks may have through holes.

The plurality of chips 94 with different specifications may be fixed on the corresponding plurality of target silicon interposer blocks. The plurality of chips 94 may be fixed on the side of the substrate 93 that originally have the grooves, or may be fixed on the newly exposed side of the substrate 93 after being thinned, to complete the interconnection and arrangement of the plurality of chips on the plurality of target silicon interposer blocks.

Further, redistribution (RDL), bumping, etc. may be performed on a side of the substrate and a side of the plurality of target silicon interposer blocks without bonding with chips, for more possible operations in the process, such as stacking of chips, etc.

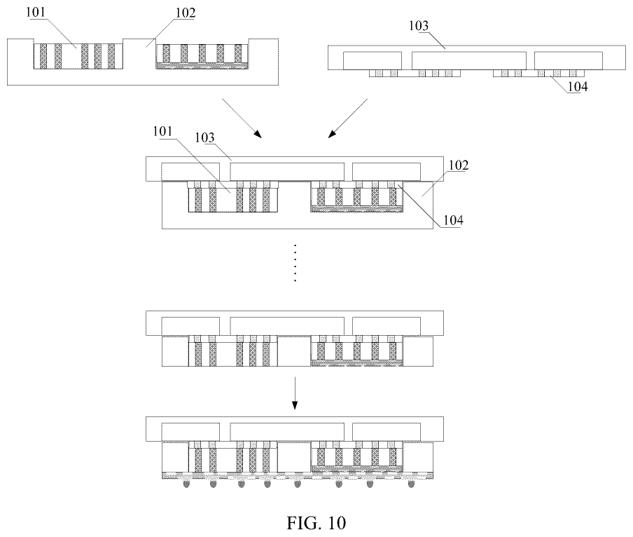

In another embodiment shown in FIG. 10, a plurality of target silicon interposer blocks 101 with through holes, and a substrate 102 with grooves etched in advance may be selected. The height of one of the plurality of target silicon interposer blocks 101 may be lower than or equal to the height of the grooves on the substrate 102.

The plurality of target silicon interposer blocks 101 may be fixed in the corresponding grooves on the substrate 102 respectively.

Subsequently, a bonding structure 104 may be provided on the previously mentioned chip reassembly 103 at a position corresponding to the one of the plurality of target silicon interposer blocks 101 with the height lower than the grooves. The height of this bonding structure 104 may be exactly equal to the height difference between the height of the one of the plurality of target silicon interposer blocks 101 and the grooves.

The chip reassembly 103 may be interconnected and arranged on the plurality of target silicon interposer blocks 101 through the bonding structure 104.

Further, the side of the substrate away from the grooves may be thinned later until the plurality of target silicon interposer blocks is exposed, and redistribution (RDL), bumping, etc. may be performed on the thinned surface for more possible operations in the process, such as stacking of chips, etc.

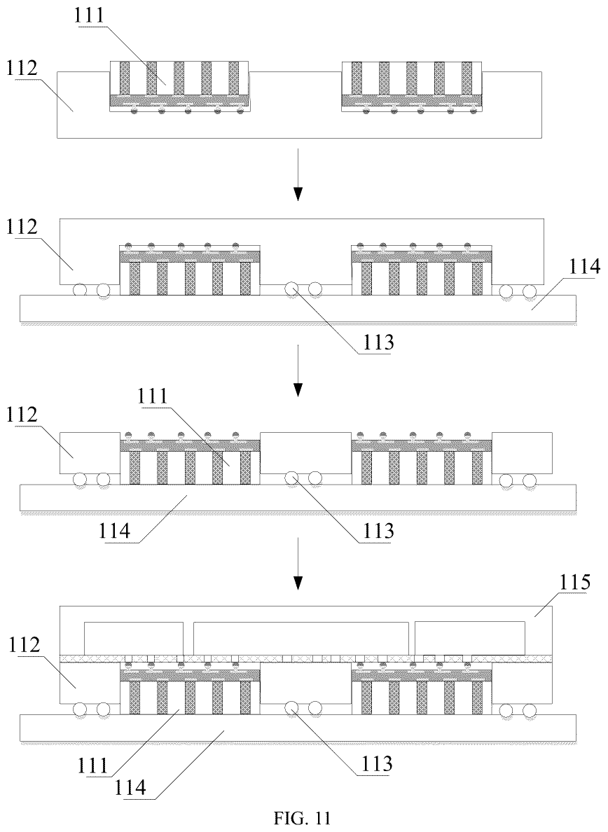

In another embodiment shown in FIG. 11, a plurality of target silicon interposer blocks 111 with through holes, and a substrate 112 with grooves etched in advance may be selected. The height of all of the plurality of target silicon interposer blocks 111 may be same and higher than the height of the grooves on the substrate 112.

The plurality of target silicon interposer blocks 111 may be fixed in the corresponding grooves on the substrate 112 respectively, with the blind hole opening direction facing inward. And bumping may be performed on the surface of the substrate 112 other than the grooves. The height of the formed bumps 113 may be same as the height difference between the plurality of target silicon interposer blocks 111 and the grooves.

A flat packaging substrate 114 may be provided and fixed on the bumps 113, that is, fixed on the plurality of target silicon interposer blocks 111. Gaps between the substrate 112, the packaging substrate 114, and the bumps 113 may be filled with underfills.

A side of the substrate 112 away from the substrate 114 may be polished and thinned to expose the plurality of target silicon interposer blocks 111. The chip reassembly 115 may be interconnected and arranged on the plurality of target silicon interposer blocks 111.

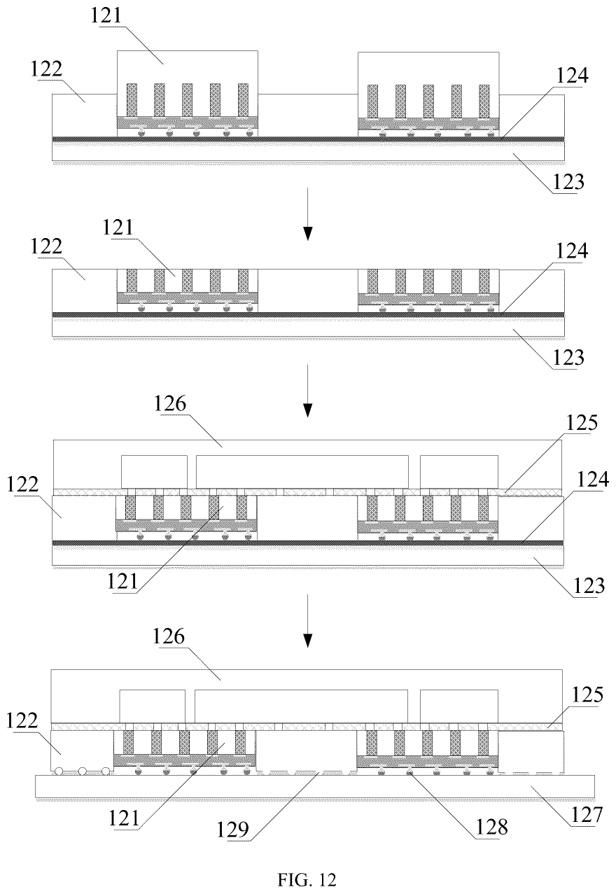

In another embodiment shown in FIG. 12, a plurality of target silicon interposer blocks 121 with blind holes and a substrate 122 with through-grooves etched in advance may be selected. A temporary carrier board 123 may be provided. A film 124 may be pasted on one side of the temporary carrier board 123, and the substrate 122 may be adhered to the temporary carrier board 123 through the film 124.

The plurality of target silicon interposer blocks 121 may be fixed in the corresponding grooves on the substrate 122 respectively, with the blind hole opening direction facing inward, and may be adhered to the temporary carrier board 123 at the same time. The height of all of the plurality of target silicon interposer blocks 121 may be higher than the height of the through grooves, and the height of the blind holes may be larger than or equal to the height of the through grooves.

A side of the plurality of target silicon interposer blocks 121 away from the temporary carrier plate 123 may be polished and thinned until the height of the plurality of target silicon interposer blocks 121 is the same as the substrate 122. A bonding structure 125 may be formed on the thinned surface.

The aforementioned chip reassembly 126 may be interconnected and arranged on the corresponding plurality of target silicon interposer blocks 121 through the bonding structure 125, and then the temporary carrier board 123 may be removed. A packaging substrate 127 may be provided to replace the original temporary carrier board 123, and may be adhered to the substrate 122 and the plurality of target silicon interposer blocks 121.

As shown in FIG. 12, when the side of the plurality of target silicon interposer blocks 121 attached to the temporary carrier board is provided with bumps 128, the bumps 128 may protrude from the surface of the substrate 122 after the temporary carrier board 123 is removed. At this time, bumping may be performed on the surface of the substrate 122 except for the through grooves, and the height of formed bumps 129 may be exactly equal to the height of the protruding portions of the bumps 129 on the plurality of target silicon interposer blocks 129 from the surface of the substrate. The packaging substrate 127 may be adhered to all the bumps, and the gaps may be filled with underfill glue.

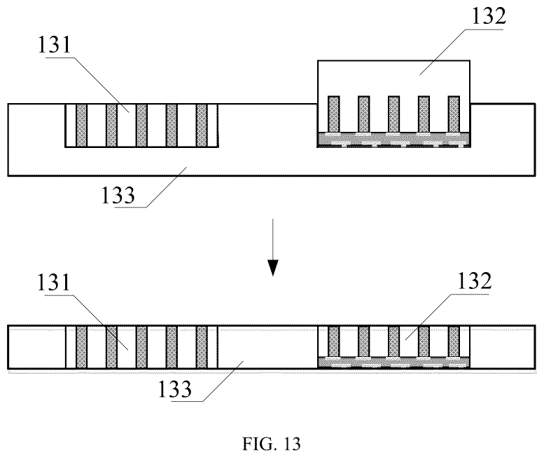

In another embodiment shown in FIG. 13, a plurality of target silicon interposer blocks 131 with through holes, a plurality of target silicon interposer blocks 132 with blind holes, and a substrate 133 with grooves etched in advance may be selected.

The plurality of target silicon interposer blocks 131 may be fixed in the corresponding grooves of the substrate 133, and its thickness may be exactly the same as the grooves. The plurality of target silicon interposer blocks 132 may be fixed in the corresponding grooves of the substrate 133 with the blind hole opening direction facing inward, its thickness may be larger than the height of the grooves, and the height of the blind holes may exceed the grooves.

A side of the plurality of target silicon interposer blocks 132 away from the substrate 133 may be polished and thinned such that the height of the plurality of target silicon interposer blocks 132 is the same as the substrate 133. At this time, the blind holes of the plurality of target silicon interposer blocks 132 may be exposed and become through holes. A side of the substrate 133 that has not been etched with grooves may be ground and thinned until all the plurality of target silicon interposer blocks are exposed.

The aforementioned chip reassembly may be interconnected and arranged on any side of the substrate 133 through the plurality of target silicon interposer blocks.

Further, redistribution (RDL), bumping, etc. may be performed on a side of the substrate and a side of the plurality of target silicon interposer blocks without bonding with chips, for more possible operations in the process, such as stacking of chips, etc.

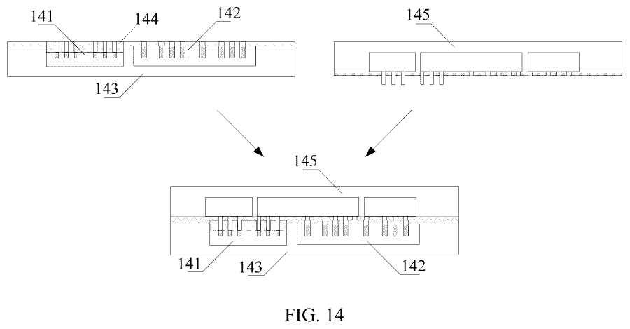

In another embodiment shown in FIG. 14, a plurality of target silicon interposer blocks with blind holes of different heights and a substrate 143 with etched grooves may be selected. The thickness of some of the plurality of target silicon interposer blocks 141 may be less than the height of the grooves, and the thickness of the remaining portion of the plurality of target silicon interposer blocks 142 may be exactly equal to the height of the grooves.

The plurality of plurality of target silicon interposer blocks may be fixed in the corresponding grooves of the substrate 143 with the blind hole opening direction facing outward. A bonding structure may be formed on the chip reassembly 145. A portion of the bonding structure corresponding to positions of the blind holes of the plurality of target silicon interposer blocks may be higher, and its height may be exactly equal to the height difference between the plurality of target silicon interposer blocks 141 and the grooves.

A passivation layer 144 may be integrally formed on the side of the substrate with the grooves. The passivation layer 144 may fill the remaining space in the grooves where the plurality of target silicon interposer blocks 141 is located, and its outer surface may be a flat surface. Through holes may be formed on the passivation layer 144 at positions corresponding to the blind holes in the plurality of target silicon interposer blocks 141, and protrusions may be provided at positions corresponding to the blind holes in the plurality of target silicon interposer blocks 142.

Finally, the chip reassembly 145 may be interconnected and disposed on the plurality of target silicon interposer blocks through bonding structures.

The side of the substrate 143 away from the chips may be polished and thinned to expose the blind holes of the plurality of target silicon interposer blocks. Redistribution (RDL), bumping, etc. may be performed on the thinned surface, for more possible operations in the process, such as stacking of chips, etc.

In various embodiments of the present disclosure, the bonding structure may include copper protrusions on the surface of the carrier (the substrate, the chip or the silicon interposer), and a SiO₂ layer or a SiCN layer (e.g., collectively called a passivation layer) around the copper protrusions with the same height. In some embodiments of the present disclosure, the process of combining the plurality of chips into a chip reassembly to be interconnected and installed on the plurality of target silicon interposer blocks as a whole may be not used. Instead, a bonding method where a single chip is flipped and installed separately and then underfilled as a whole (FC) may be adopted.

The present disclosure also provides a chip packaging structure. The chip packaging structure may include: a plurality of silicon interposers, a first plastic encapsulation layer, and a plurality of chips. Each of the plurality of silicon interposers may be provided with conductive connection structures, and conductive connection structures of at least one of the plurality of silicon interposers may be different from conductive connection structures of others of the plurality of silicon interposers. The first plastic encapsulation layer may wrap the plurality of silicon interposers. The plurality of chips may be interconnected to the plurality of silicon interposers through a bonding structure.

For the detailed implementation of the chip packaging structure embodiments, the reference may be made to the previous method embodiments.

In the chip packaging process, various types of substrates and different types of target silicon interposer blocks may be used according to various packaging requirements. The embodiments of the present disclosure provide packaging operation steps for specific target silicon interposer block and substrate combinations in some cases. It can be seen that the chip packaging method of the present disclosure has high universality.

In the present disclosure, the large silicon interposer plate may be cut into small silicon interposer blocks to avoid warping and cracking of the silicon interposers during the thinning process. The plurality of silicon interposer blocks with different specifications may be combined according to the installation requirements of different chips, and may be installed with the corresponding chips. Also, the plurality of chips and the plurality of silicon interposer blocks may be molded simultaneously at one time. The overall area of the silicon interposers and the spacing between individual chips may be reduced, greatly improving packaging efficiency and overall integration level.

The embodiments disclosed herein are exemplary only. Other applications, advantages, alternations, modifications, or equivalents to the disclosed embodiments are obvious to those skilled in the art and are intended to be encompassed within the scope of the present disclosure.

What is claimed is:

1. A chip packaging method, comprising:
providing a substrate, a plurality of silicon wafers, and a plurality of chips;
forming a plurality of sets of conductive connection structures on the plurality of silicon wafers respectively to form a plurality of silicon interposer plates; wherein at least one of the plurality of silicon interposer plates is different from other silicon interposer plates of the plurality of silicon interposer plates;
cutting the plurality of silicon interposer plates respectively to obtain a plurality of silicon interposer blocks;
selecting a plurality of target silicon interposer blocks from the plurality of silicon interposer blocks, and fixing the plurality of target silicon interposer blocks on the substrate; and
interconnecting and arranging the plurality of chips on corresponding target silicon interposer blocks of the plurality of target silicon interposer blocks respectively.

2. The method according to claim 1, wherein:
each of the plurality of silicon wafers includes a first surface and a second surface along its thickness direction; and
forming the plurality of sets of conductive connection structures on the plurality of silicon wafers respectively to form the plurality of silicon interposer plates, includes:
forming a plurality sets of blind holes on the first surface of at least one of the plurality of silicon wafers; and
filling the plurality of sets of blind holes with conductive materials to form the plurality of sets of conductive connection structures and the plurality of silicon interposer plates.

3. The method according to claim 1, wherein:
each of the plurality of silicon wafers includes a first surface and a second surface along its thickness direction; and
forming the plurality of sets of conductive connection structures on the plurality of silicon wafers respectively to form the plurality of silicon interposer plates, includes:
forming a plurality sets of blind holes on the first surface of at least one of the plurality of silicon wafers; and
filling the plurality of sets of blind holes with conductive materials to form the plurality of sets of conductive connection structures; and
thinning the second surfaces of the plurality of silicon wafers until exposing the plurality of sets of blind holes to form silicon through holes and the plurality of silicon interposer plates.

4. The method according to claim 1, wherein:
each of the plurality of silicon wafers includes a first surface and a second surface along its thickness direction; and
forming the plurality of sets of conductive connection structures on the plurality of silicon wafers respectively to form the plurality of silicon interposer plates, includes:
forming a plurality sets of blind holes on the first surface of at least one of the plurality of silicon wafers; and
filling the plurality of sets of blind holes with conductive materials; and
forming a redistribution layer on the first surfaces of the plurality of silicon wafers to form the plurality of sets of conductive connection structures and the plurality of silicon interposer plates.

5. The method according to claim 1, wherein:
each of the plurality of silicon wafers includes a first surface and a second surface along its thickness direction; and
forming the plurality of sets of conductive connection structures on the plurality of silicon wafers respectively to form the plurality of silicon interposer plates, includes:
forming a plurality sets of blind holes on the first surface of at least one of the plurality of silicon wafers; and
filling the plurality of sets of blind holes with conductive materials; and
forming a redistribution layer on the first surfaces of the plurality of silicon wafers to form the plurality of sets of conductive connection structures; and
thinning the second surfaces of the plurality of silicon wafers until exposing the plurality of sets of blind holes to form silicon through holes and the plurality of silicon interposer plates.

6. The method according to claim 1, wherein:
each of the plurality of silicon wafers includes a first surface and a second surface along its thickness direction; and
forming the plurality of sets of conductive connection structures on the plurality of silicon wafers respectively to form the plurality of silicon interposer plates, includes:
forming a plurality sets of blind holes on the first surface of at least one of the plurality of silicon wafers; and
filling the plurality of sets of blind holes with conductive materials; and
forming a redistribution layer on the first surfaces of the plurality of silicon wafers; and
forming bumps on the redistribution layer to form the plurality of sets of conductive connection structures and the plurality of silicon interposer plates.

7. The method according to claim 1, wherein:
each of the plurality of silicon wafers includes a first surface and a second surface along its thickness direction; and
forming the plurality of sets of conductive connection structures on the plurality of silicon wafers respectively to form the plurality of silicon interposer plates, includes:
forming a plurality sets of blind holes on the first surface of at least one of the plurality of silicon wafers; and
filling the plurality of sets of blind holes with conductive materials; and
forming a redistribution layer on the first surfaces of the plurality of silicon wafers; and
forming bumps on the redistribution layer to form the plurality of sets of conductive connection structures; and
thinning the second surfaces of the plurality of silicon wafers until exposing the plurality of sets of blind holes to form silicon through holes and the plurality of silicon interposer plates.

8. The method according to claim 1, wherein:
fixing the plurality of target silicon interposer blocks on the substrate includes fixing each of the plurality of target silicon interposer blocks at a corresponding position on the substrate; and
after fixing the plurality of target silicon interposer blocks on the substrate, the method further includes: prefabricating a plurality of conductive pillars on one side of the substrate facing the plurality of target silicon interposer blocks and performing plastic encapsulation on the plurality of conductive pillars and the plurality of target silicon interposer blocks on the substrate; or, performing plastic encapsulation on the plurality of target silicon interposer blocks on the substrate to form a plastic encapsulation layer, forming a plurality of through holes along the thickness direction of the plastic encapsulation layer, and filling the plurality of through holes with conductive materials to form the plurality of conductive pillars, wherein the plurality of conductive pillars is used to electrically connect the substrate and the plurality of chips.

9. The method according to claim 1, wherein:
a plurality of grooves is provided on a side of the substrate facing the plurality of target silicon interposer blocks; and
fixing the plurality of target silicon interposer blocks on the substrate further includes fixing each of the plurality of target silicon interposer blocks in a corresponding groove of the plurality of grooves on the substrate.

10. The method according to claim 1, wherein:
a plurality of through grooves is provided in the substrate along a thickness direction of the substrate; and
fixing the plurality of target silicon interposer blocks on the substrate further includes:
fixing the substrate to a temporary carrier board; and fixing each of the plurality of target silicon interposer blocks in a corresponding one of the plurality of through grooves and to the temporary carrier board.

11. The method according to claim 1, wherein:
fixing the plurality of target silicon interposer blocks on the substrate includes: fixing second surfaces of the plurality of target silicon interposer blocks on the substrate.

12. The method according to claim 11, wherein:
after fixing the second surfaces of the plurality of target silicon interposer blocks on the substrate, the method further includes: forming a first bonding structure on the first surfaces of the plurality of target silicon interposer blocks; and forming a second bonding structure on front surfaces of the plurality of chips;
and
interconnecting and arranging the plurality of chips on the corresponding target silicon interposer blocks of the plurality of target silicon interposer blocks respectively includes: fixing the first bonding structure with the second bonding structure to achieve the interconnection and arrangement of the plurality of chips on the plurality of target silicon interposer blocks.

13. The method according to claim 11, wherein:
after fixing the second surfaces of the plurality of target silicon interposer blocks on the substrate, the method further includes forming conductive protrusions on front surfaces of the plurality of chips;
and
interconnecting and arranging the plurality of chips on the corresponding target silicon interposer blocks of the plurality of target silicon interposer blocks respectively includes: fixing the conductive protrusions on the first surfaces of the plurality of target silicon interposer blocks; and filling underfill glues between the plurality of chips and the plurality of target silicon interposer blocks, to achieve the interconnection and arrangement of the plurality of chips on the plurality of target silicon interposer blocks.

14. The method according to claim 9, wherein:
fixing each of the plurality of target silicon interposer blocks in a corresponding groove of the plurality of grooves on the substrate includes: fixing a first surface of at least one of the plurality of target silicon interposer blocks in a corresponding groove and fixing second surfaces of remaining target silicon interposer blocks of the plurality of target silicon interposer blocks in corresponding grooves, wherein the plurality of target silicon interposer blocks has same thickness;
and
after fixing the first surface of the at least one of the plurality of target silicon interposer blocks in a corresponding groove and fixing the second surfaces of the remaining target silicon interposer blocks of the plurality of target silicon interposer blocks in corresponding grooves, the method further includes:
thinning a back surface of the substrate until exposing all the plurality of target silicon interposer blocks.

15. The method according to claim 14, wherein interconnecting and arranging the plurality of chips on the corresponding target silicon interposer blocks of the plurality of target silicon interposer blocks respectively includes:
fixing the plurality of chips on a front surface of the substrate; or
fixing the plurality of chips on the back surface of the substrate.

16. The method according to claim 14, after interconnecting and arranging the plurality of chips on the corresponding target silicon interposer blocks of the plurality of target silicon interposer blocks respectively, further including:
forming a redistribution layer on a side of the substrate without fixing the plurality of chips; and
forming bumps on a surface of the redistribution layer.

17. The method according to claim 9, wherein:
at least one of the plurality of target silicon interposer blocks has a thickness lower than the height of the plurality of grooves on the substrate;
the plurality of chips is fixed on a carrier for plastic encapsulation, and then the carrier is removed to obtain chip reassemblies;
after fixing the plurality of target silicon interposer blocks on the substrate, the method further includes: forming a bonding structure on front surfaces of the chip reassemblies; and
interconnecting and arranging the plurality of chips on the corresponding target silicon interposer blocks of the plurality of target silicon interposer blocks respectively includes: fixing the chip reassemblies on first surfaces of the corresponding target silicon interposer blocks of the plurality of target silicon interposer blocks respectively through the bonding structure, to achieve the interconnection and arrangement of the plurality of chips on the plurality of target silicon interposer blocks.

18, The method according to claim 16, after fixing the plurality of target silicon interposer blocks in the corresponding grooves on the substrate, further including:
forming a bonding structure at a position of the chip reassemblies corresponding to the at least one of the plurality of target silicon interposer blocks with the thickness lower than the height of the plurality of grooves on the substrate.

19. The method according to claim 9, wherein:
at least one of the plurality of target silicon interposer blocks has a thickness higher than the height of the plurality of grooves on the substrate; and
after fixing the plurality of target silicon interposer blocks in the corresponding grooves on the substrate, the method further includes: thinning second surfaces of the at least one of the plurality of target silicon interposer blocks with the thickness higher than the height of the plurality of grooves until the thickness of the plurality of target silicon interposer blocks equals to the thickness higher than the height of the plurality of grooves and the plurality of blind holes of the plurality of target silicon interposer blocks is exposed.

20. A chip packaging structure, comprising:
a plurality of silicon interposers, wherein each of the plurality of silicon interposers is provided with conductive connection structures and conductive connection structures of at least one of the plurality of silicon interposers are different from conductive connection structures of others of the plurality of silicon interposers; and
a plurality of chips, wherein the plurality of chips is interconnected to the plurality of silicon interposers through a bonding structure.
